(19) United States
(12) Patent Application Publication
(10) Pub. No.: US 2023/0387238 A1
(43) Pub. Date: Nov. 30, 2023

(54) METHOD AND STRUCTURE FOR FORMING LOW CONTACT RESISTANCE COMPLEMENTARY METAL OXIDE SEMICONDUCTOR

(71) Applicant: International Business Machines Corporation, Armonk, NY (US)

(72) Inventors: Ruilong Xie, Niskayuna, NY (US); Julien Frougier, Albany, NY (US); Andrew M. Greene, Slingerlands, NY (US); REINALDO VEGA, Mahopac, NY (US)

(21) Appl. No.: 17/664,712

(22) Filed: May 24, 2022

(51) Int. Cl. H01L 29/45; H01L 27/092; H01L 29/08; H01L 21/8238

(52) U.S. Cl. CPC H01L 29/45; H01L 27/0924; H01L 29/0847; H01L 21/823821; H01L 21/823814; H01L 21/823878; H01L 21/823871

(57) ABSTRACT

A complementary metal oxide semiconductor (CMOS) device. The device includes a pFET epi and an nFET epi. The pFET epi includes a single dielectric layer that wraps around a first portion of the pFET epi and a confined trench epi on a second portion of the pFET epi that is adjacent a first contact. The nFET epi includes a bi-layer dielectric liner that wraps around a first portion of the nFET epi and a second portion of the nFET epi that is adjacent a second contact.

### BACKGROUND

The present disclosure relates to complementary metal oxide semiconductor (CMOS) structures and methods of forming the same. More particularly, the present disclosure provides a method of forming CMOS structures having low contact resistance.

Complementary metal-oxide-semiconductor (CMOS) technology may be used to form integrated circuits (ICs), useful in various applications including but not limited to microprocessors, microcontrollers, logic circuits, static random access memory (RAM), etc. CMOS field effect transistors (FETs) are employed in almost every electronic circuit application such as signal processing, computing, and wireless communications.

### SUMMARY

According to some embodiments of the disclosure, there is provided a CMOS device. The device includes a pFET epi and an nFET epi. The pFET epi includes a single dielectric layer that wraps around a first portion of the pFET epi and a confined trench epi on a second portion of the pFET epi that is adjacent a first contact. The nFET epi includes a bi-layer dielectric liner that wraps around a first portion of the nFET epi and a second portion of the nFET epi that is adjacent a second contact.

According to some embodiments of the disclosure, there is provided a semiconductor structure. The structure includes a first field-effect transistor (FET) having a first source/drain (S/D), wherein the first S/D comprises an nFET material. The structure also includes a second FET having a second S/D, wherein the second S/D comprises a pFET material. Also, the structure includes an epi layer containing germanium (Ge) and located on the second S/D.

According to some embodiments of the disclosure, there is provided a method of forming a CMOS structure. One operation in the method or process is forming an nFET epi on a substrate in a first S/D region. Another operation is depositing a first dielectric liner over the nFET epi. A further operation is forming a pFET epi on the substrate in a second S/D region. Yet another operation is depositing a second dielectric liner over both the pFET epi and the first dielectric liner that is deposited over the nFET epi. Another operation is depositing an interlayer dielectric (ILD) layer in the first and second S/D regions. A further operation is etching the ILD layer to remove portions of the ILD layer to form a first contact opening in the first S/D region and a second contact opening in the second S/D region, wherein during the etching, the second dielectric liner is removed within the first and second contact openings. Another operation is forming a trench epi on the pFET epi. Other operations include removing the first dielectric liner from the first contact opening, and forming a first contact in the first contact opening and a second contact in the second contact opening.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 illustrates a top view of a CMOS structure disclosed herein and includes locations of where two cross-sections are taken (at X-X and at Y-Y) that are shown in cross-sectional views in the following FIGS. 2-13, in accordance with embodiments of the disclosure;

FIGS. 2-13 each illustrate two cross-sectional views of the CMOS structure of FIG. 1, taken at X-X and Y-Y (as shown in FIG. 1), with the two views X-X and Y-Y shown side-by-side, and taken at various operations or stages in a process or method to form the CMOS structure as disclosed herein, in accordance with embodiments of the disclosure; and

FIG. 14 is a flow diagram of a process for forming a CMOS structure disclosed herein, in accordance with embodiments of the disclosure.

While the disclosure is amenable to various modifications and alternative forms, specifics thereof have been shown by way of example in the drawings and will be described in detail. It should be understood, however, that the intention is not to limit the disclosure to the particular embodiments described. On the contrary, the intention is to cover all modifications, equivalents, and alternatives falling within the spirit and scope of the disclosure.

### DETAILED DESCRIPTION

Aspects of the present disclosure relate generally to complementary metal oxide semiconductor (CMOS) structures and methods of forming the same. More particularly, the present disclosure provides a method of forming CMOS having low contact resistance. While the present disclosure is not necessarily limited to such applications, various aspects of the disclosure can be appreciated through a discussion of various examples using this context.

Embodiments of the present disclosure relate to an IC having a CMOS transistor comprising a p-type field-effect transistor (pFET) and an n-type field-effect transistor (nFET). The pFET and the nFET each have a channel region, and a source and a drain region formed in a first semiconductor region. Embodiments of the present disclosure generally relates to various methods of reducing the contact resistance between a metal silicide material and an epi semiconductor material, and the resulting semiconductor devices. Moreover, as will be readily apparent to those skilled in the art upon a complete reading of the present application, the present method is applicable to a variety of devices, including, but not limited to, logic devices, memory devices, etc. The methods and devices disclosed herein may be employed in manufacturing products using CMOS, etc., and they may be employed in manufacturing a variety of different devices, e.g., memory devices, logic devices, application-specific integrated circuits (ASICs), etc. As will be further appreciated by those skilled in the art, the disclosure can be employed in forming IC products using planar transistor devices or a variety of so-called three-dimensional (3D) devices, such as finFETs. For example, although the figures of the disclosure include a finFET, the disclosure applies to all devices, including nanosheet, nanowire, and vertical transport field effect transistor (VTFET), for example.

As is known, a finFET is a transistor built around a thin strip of semiconductor material generally referred to as the fin. The transistor includes the standard FET nodes, including a gate, a gate dielectric, a source region, and a drain region. The conductive channel of the device resides on the outer sides of the fin beneath the gate dielectric. Specifically, current runs along both sidewalls of the fin (sides perpendicular to the substrate surface) as well as along the top of the fin (side parallel to the substrate surface). Because the conductive channel of such configurations essentially resides along the three different outer, planar regions of the fin, such a finFET design is sometimes referred to as a tri-gate finFET. Other types of finFET configurations are also available, such as double-gate finFETs, in which the conductive channel principally resides only along the two sidewalls of the fin (and not along the top of the fin).

Increased performance of circuit devices including transistors, diodes, resistors, capacitors, and other passive and active electronic devices formed on a semiconductor substrate is typically considered during design, manufacture, and operation of those devices. For example, during design and manufacture or forming of, metal oxide semiconductor (MOS) transistor semiconductor devices, such as those used in a CMOS, it is often useful to reduce the parasitic resistance associated with contacts otherwise known as external resistance (Rₑₓₜ). Contact resistance (R_{contact}) has become an Rₑₓₜ bottleneck as gate pitch is scaled in the transistor, and contact area becomes smaller. To reduce the R_{contact} at a given contact area, contact resistivity may be reduced (e.g., below 2×10⁻⁹ Ωcm²).

In order to reduce contact resistivity, it has been found that it can be useful to have a relatively high percentage germanium (Ge) epi on a pFET material in a CMOS structure. However, forming a high percentage of Ge over pFET S/D epi in an early stage of the device fabrication can result in easy oxidation and Ge diffusion during subsequent processing steps with high thermal budget, such as a high-k dielectric reliability anneal. Forming a late trench Ge epi during contact formation can avoid processing steps with high thermal budget, on the other hand, and can have other drawbacks. For example, using a separate mask for the nFET in the CMOS structure during application of the trench Ge epi of Ge on the pFET of the CMOS late in the manufacturing process can be relatively costly. Also, it may be challenging to remove a protecting liner once the liner is deposited at the sidewalls of a contact trench. More specifically, isotropic liner removal can damage spacer and gate corners.

One feature and advantage of disclosed structures and processes is that formation of the trench Ge epi for only pFET devices for a CMOS application, using the disclosed process, may reduce costs in comparison to current solutions. Another feature or advantage of the disclosed process is that the process can be applicable to many technologies, such as finFET, nanosheet and VTFET, for example. Yet another feature or advantage of the disclosed process and structure is that contact resistance can be reduced.

For purposes of this disclosure, reference will be made to an illustrative process flow wherein for forming a single CMOS transistor device (“CMOS device”) 100. Of course, the disclosure herein should not be considered to be limited to the illustrative examples depicted and described herein. With reference to the attached figures, various illustrative embodiments of the methods and devices disclosed herein will now be described in more detail.

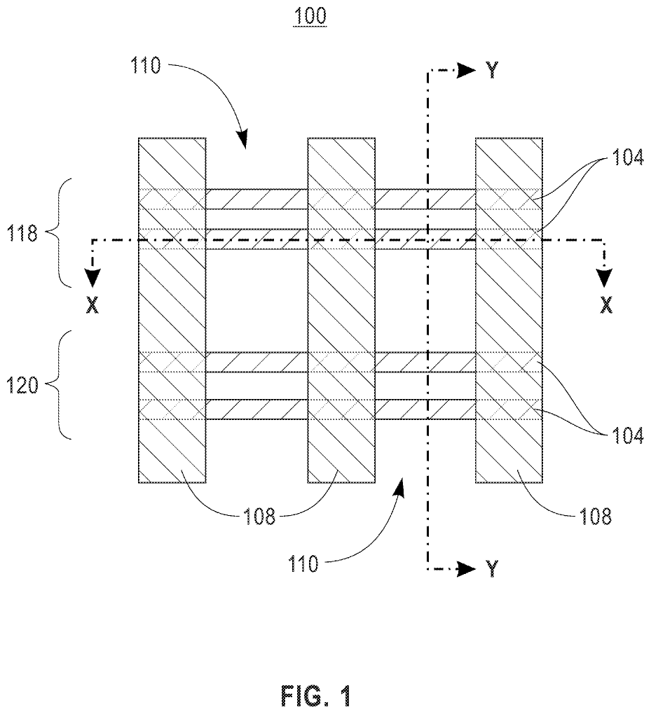

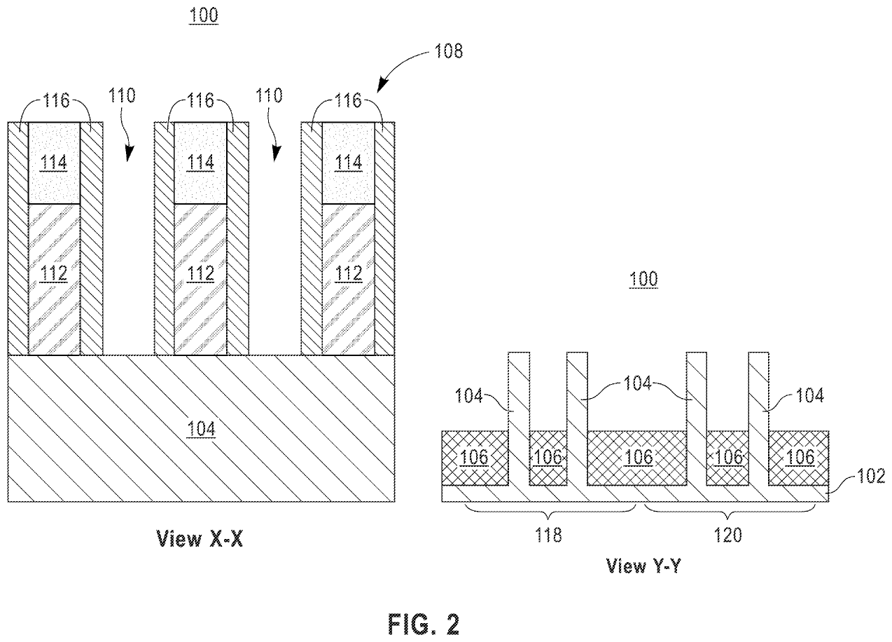

FIG. 1 illustrates a top view of a CMOS device 100 disclosed herein that contains a simplistic plan view of the structure. The figure depicts locations where cross-sectional views, as depicted in FIGS. 2-13 (at X-X and at Y-Y), were taken. More specifically, the view “X-X” is a cross-sectional view that is taken through pFET region of the CMOS device 100, and the view “Y-Y” is a cross-sectional view that is taken through S/D) regions of both pFET and nFET regions of the CMOS device 100. The figure also includes components of the CMOS structure for reference, which are discussed below with regard to FIGS. 2-13. FIGS. 2-13 each illustrate two cross-sectional views of the CMOS structure of FIG. 1, taken at X-X and Y-Y (as shown in FIG. 1), with the two views X-X and Y-Y shown side-by-side, and taken at various operations in a process to form the CMOS structure of FIG. 1.

Turning to the subsequent figures, FIGS. 2-13 include schematic illustrations of cross-sectional views of the CMOS device 100 through operations or steps of an example manufacturing process. The attached drawings present various views of one illustrative embodiment of a process or method to make the CMOS device 100 having low contact resistance. The right side of each of FIGS. 2-13 shows a cross-sectional view of S/D regions of an example finFET architecture of the CMOS device 100, in accordance with an embodiment of the disclosure (view Y-Y). The S/D regions of the CMOS device 100 includes a substrate 102 having a semiconductor body or one or more fins 104 extending from the substrate 102 through shallow trench isolation (STI) regions 106 (defining trenches therebetween), according to an embodiment of the disclosure. The left side of each of FIGS. 2-13 shows a cross-sectional view of the CMOS device 100 through one or more gate stacks 108 that are formed above the substrate 102 (view X-X).

The various layers of material depicted in the following drawings can be formed by any of a variety of different known techniques, e.g., a chemical vapor deposition (CVD) process, an atomic layer deposition (ALD) process, a thermal growth process, spin-coating techniques, reactive-ion etching (RIE), etc.

The terms “epitaxially,” “epitaxy,” “epi,” etc., carry their customary usage: meaning the single crystal lattice structure carries across an interface. Typically, a single crystal material forms a platform onto which another single crystal material, with matching crystalline characteristics, can be deposited by one of several techniques known in the art. Such techniques are, for instance, molecular beam epitaxy (MBE), or various types of CVD.

FIG. 2 shows an operation in the process of manufacturing the CMOS device 100 having low contact resistance. The substrate 102 can have a variety of configurations, such as the depicted bulk substrate configuration. The substrate 102 can have an SOI configuration wherein the semiconductor devices are formed in the active layer of the SOI substrate. The substrate 102 can be made of silicon or it may be made of materials other than silicon, which may or may not be combined with silicon, such as germanium, silicon germanium, indium antimonide, lead telluride, indium arsenide, indium phosphide, gallium arsenide, or gallium antimonide. Any suitable material that can serve as a foundation upon which a semiconductor device can be built can be used in accordance with embodiments of the present disclosure. Thus, the terms “substrate,” “semiconductor substrate” or “semiconducting substrate” should be understood to cover all semiconducting materials and all forms of such materials.

FIG. 2 illustrates the substrate 102 having a plurality of the fins 104 over which a gate stack 108 is formed, according to an embodiment of the disclosure. The fins 104 can be formed, for example, from the substrate 102 that can be bulk silicon or from the top layer of the substrate 102 having an SOI configuration. The fins 104 can be formed using a lithographic patterning and etching process such as RIE, for example, or another suitable fabrication process.

As shown in the Y-Y view, the fins 104 extend through the STI regions 106. The STI regions 106 can be formed using conventional techniques, such as by performing additional patterning steps to remove any unwanted fins, then depositing dielectric material onto the trenches followed by planarization and recessing to form the STI regions 106. The STI regions 106 can be made from any suitable insulating material, such as SiO₂ or a thin SiN liner followed by SiO₂.

A plurality of gate stacks 108 (see X-X view) can be formed over a number of surfaces of the fins 104 to form gates. Three (3) gate stacks 108 are shown in the figures. In the operation shown in FIG. 2, the gate stacks 108 includes a “dummy” or sacrificial gate structure 112, that can comprise one or more sacrificial layers that act as the placeholder for gates, e.g., it can be formed by deposition of a thin layer of SiO₂, followed by polysilicon (or amorphous Si), etc. After dummy gate structure deposition, a gate hardmask layer 114 (i.e., a silicon nitride layer) can then be deposited atop the dummy gate structures 112 followed by a gate patterning process using conventional lithography and an etching process, for example. Further, gate sidewall spacers 116 (e.g., silicon nitride spacers or low-k nitride spacers) can be formed, which both can encapsulate and protect the dummy gate structure 112. The spacers 116 can be formed by depositing a layer of spacer material adjacent the dummy gate structure 112 and thereafter performing an anisotropic etching process on the layer of spacer material. The width of the spacers 116 can generally be chosen based on design requirements for the CMOS device 100 being formed.

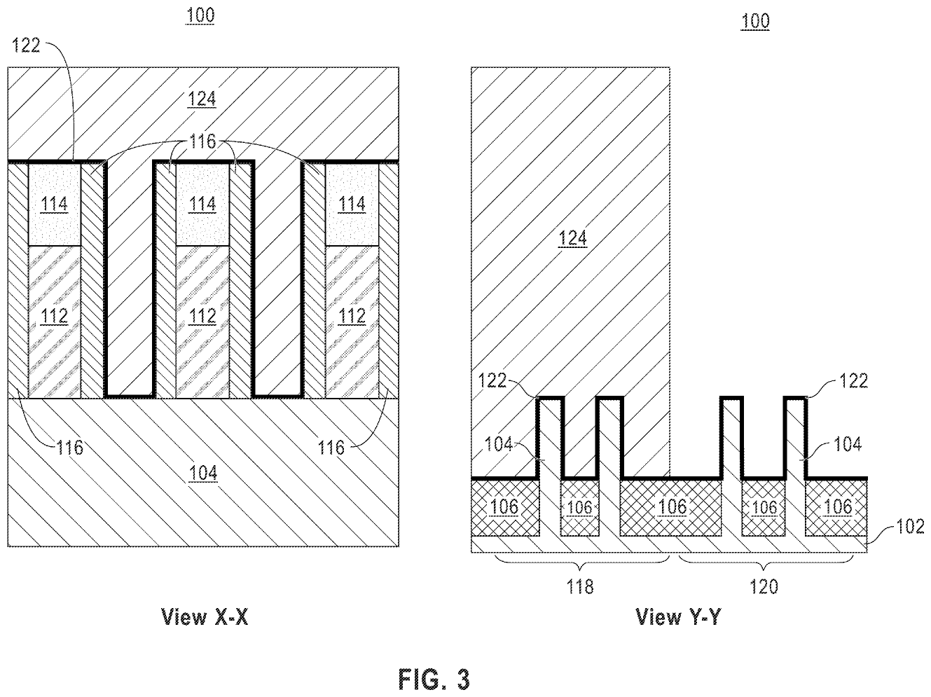

Turning to FIG. 3, a next operation (or operations) is shown in the process to form the CMOS device 100. The CMOS device 100 has two regions (see view Y-Y), which include a pFET region 118 and an nFET region 120. The pFET region 118 is an area of the CMOS device 100 that eventually will include a pFET, as formed in described subsequent operations. The nFET region 120 is an area of the CMOS device 100 that eventually will include an nFET, as formed in described subsequent operations. As shown, a patterning liner (e.g., silicon nitrate (SiN) layer) 122 can be deposited over the fins 104 and the STI regions 106 in both the pFET region 118 and the nFET region 120. SiN is one example of a material used for the layer 122, however, other suitable materials are also contemplated.

A mask layer 124 (e.g., organic planarization layer (OPL)) 124 can be deposited and patterned, such that the patterning layer 122 in the pFET region is covered by the mask layer 124, and the patterning layer 122 in the nFET region 120 is exposed. The mask layer or OPL 124 can be deposited using a spin-on deposition process, for example. It is useful for the mask layer 124 to have certain properties. For example, the mask layer 124 is sacrificial, so it can be a material that can be removed easily without damaging the surrounding structure. Further, the mask layer 124 can have useful “gap-fill” properties so that the mask layer 124 can fill trenches. Additionally, the mask layer 124 can be self-planarizing. Also, the mask layer 124 can be composed of a material that is easily etch-selective relative to the patterning layer 122.

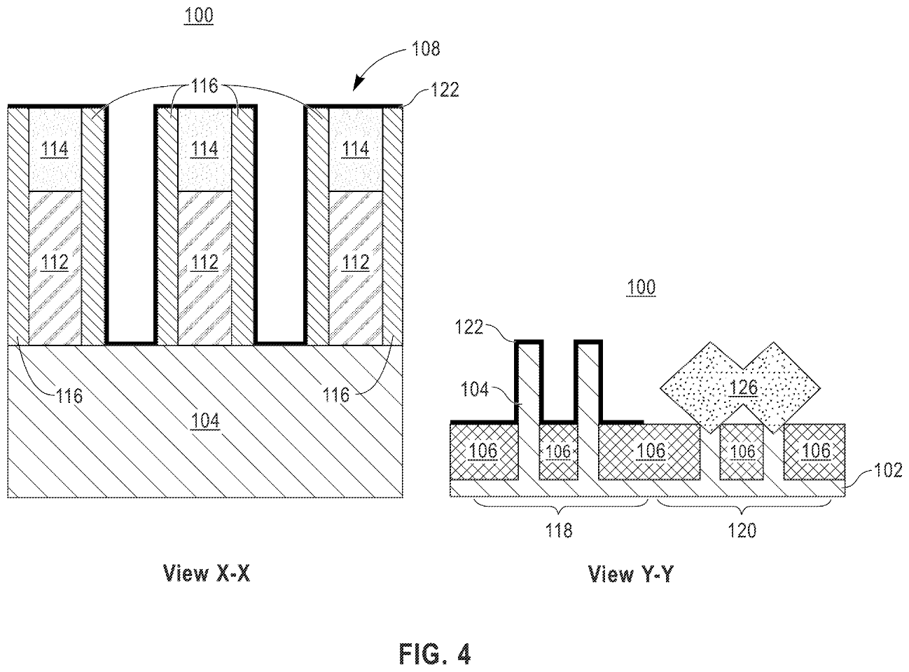

FIG. 4 illustrates a next operation (or operations) in the process of forming the CMOS device 100. As shown, with mask layer 124 still covering the pFET region 118 (as in FIG. 3), the patterning (SiN) layer 122 in the nFET region 120 is removed, and, after that, the exposed fins 104 in nFET region 120 are recessed. Additionally, the mask layer 124 can be removed, using conventional process, such as ashing. FIG. 4 (in the Y-Y view) also illustrates the CMOS device 100 after growth of S/D epitaxial material 126 in the nFET region 120.

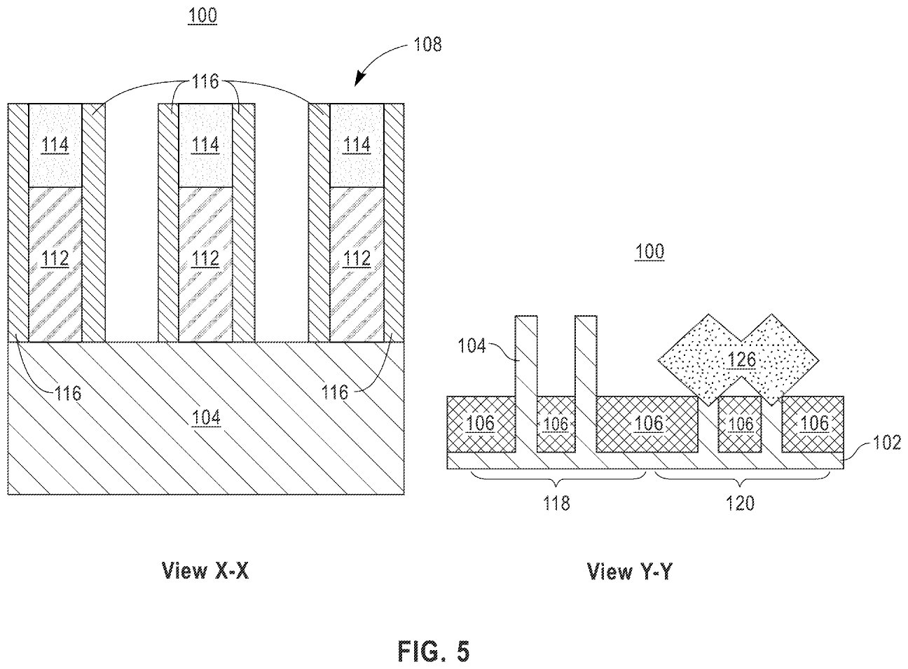

FIG. 5 shows the CMOS device 100 after a next operation is performed. The patterning layer 122 has been selectively removed from the fins 104 in the pFET region 118.

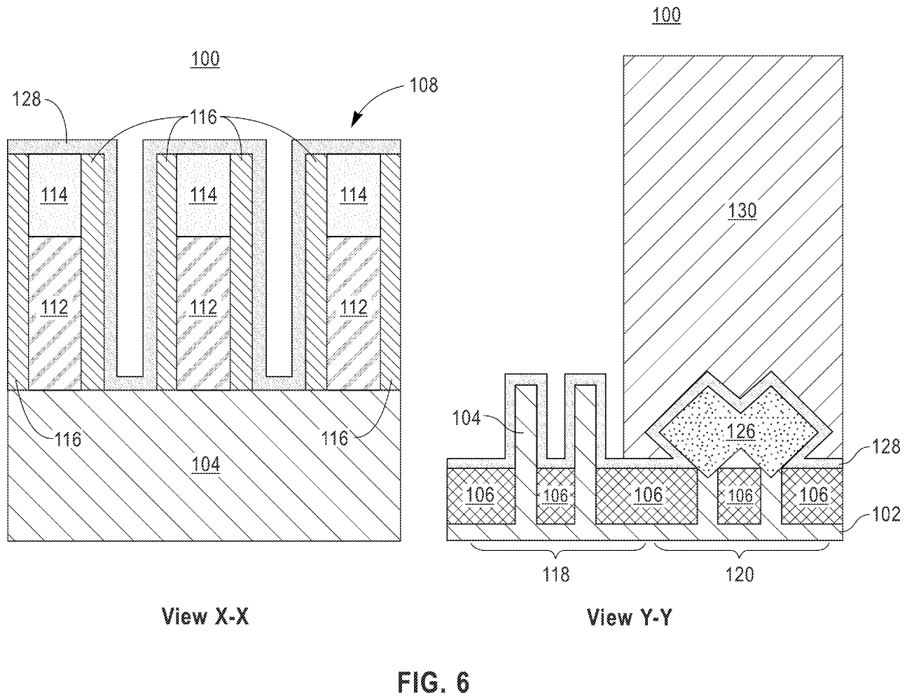

FIG. 6 illustrates the CMOS device 100 after another operation or operations. The figure shows a dielectric liner 128 (a first dielectric liner) comprising silicon oxycarbide (SiOC) 128 deposited overlying the gate stacks 108, the fins 104 in the pFET region 118, and the nFET epi 126. A second patterning layer 130 is shown (in view Y-Y) deposited and patterned over the nFET region 120. The first dielectric liner 128 can be comprised of any suitable material, with examples being SiOC, SiC or SiOCN, etc.

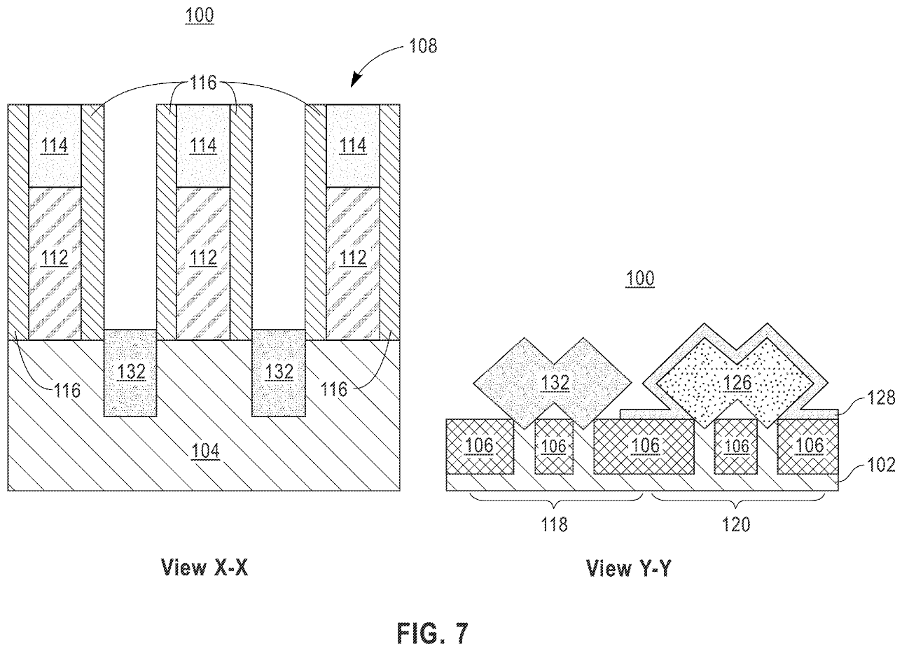

Next, in FIG. 7, a next operation in the process of forming the CMOS device 100 is shown. With the nFET region 120 being covered by the patterning layer 130, the first dielectric liner 128 in pFET region 118 is shown removed, which was followed by fin recess. The first dielectric liner 128 was, therefore, left behind in the nFET region 120, and is wrapped around the nFET epi 126. After that, the patterning layer 130 is shown removed, which can be accomplished by conventional process, such as ashing. FIG. 7 also illustrates the CMOS device 100 after growth of epitaxial S/D epi 132 material in the pFET region 118.

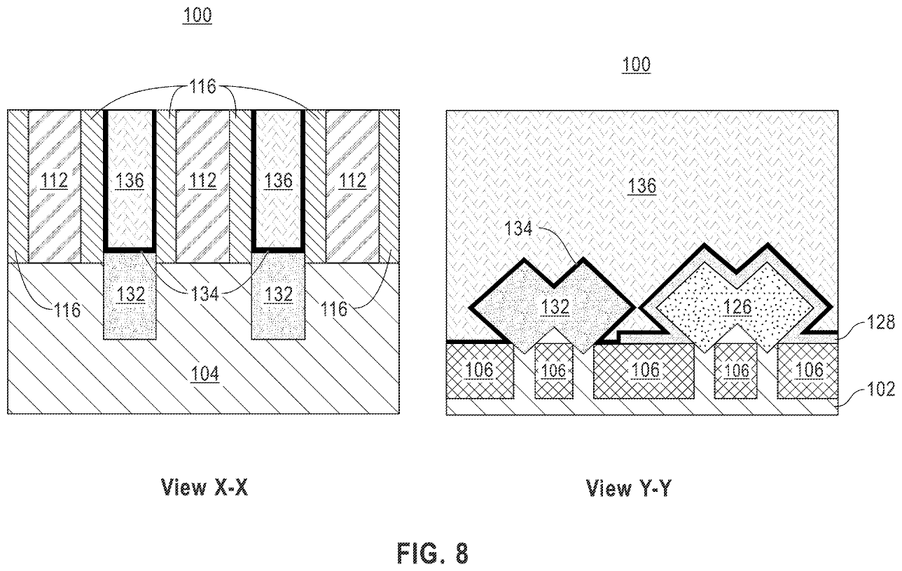

FIG. 8 illustrates the CMOS device 100 after another operation or operations. A second dielectric liner (e.g., a SiN layer) 134 is shown deposited over and wrapped around both the pFET epi 132 and the first dielectric liner 128 that is wrapped around the nFET epi 126 in a channel region 110. Also, an ILD layer 136 is shown deposited in the channel region 110 over the second dielectric liner 134.

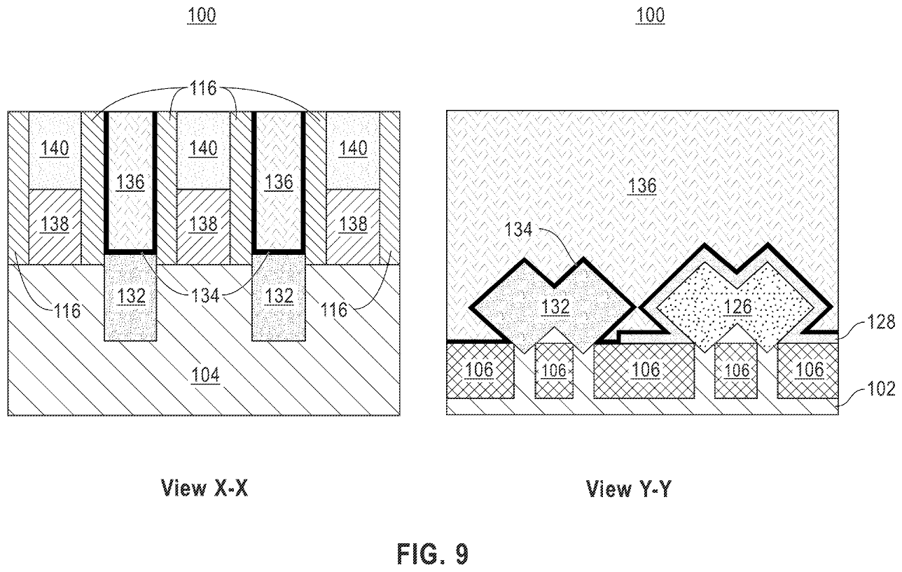

FIG. 9 (in view X-X) shows the CMOS device 100 after another operation or operations. the dummy gate structure 112 is shown selectively removed with respect to the surrounding materials, followed by deposition of a high-k metal gate (HKMG) 138. The HKMG 138 can be optionally recessed, followed by deposition of a dielectric cap 140 for self-aligned contact formation (otherwise known as an “SAC cap”).

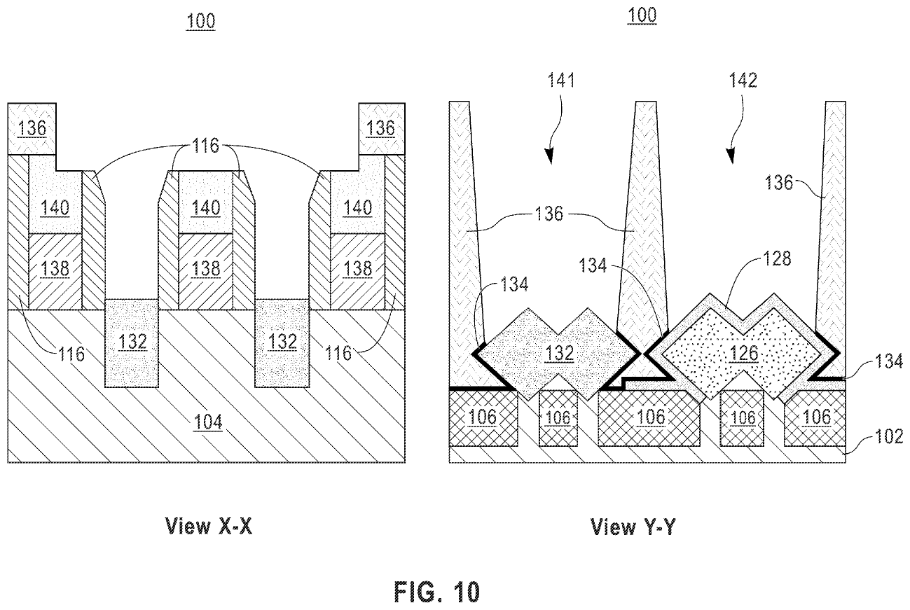

FIG. 10 depicts the CMOS device 100 after one or more patterning and etching processes were performed through a patterned etch mask (not shown) to remove portions of the ILD layer 136 (see FIG. 9) to thereby define a plurality of trenches (or contact openings) 141, 142. RIE can be used, for example, to etch the ILD layer 136. The etching process(es) exposes the first dielectric liner 128, which wraps around the nFET epi 126, and pFET epi 132. The second dielectric liner 134 is shown removed towards the openings in the trenches 141, 142. The second dielectric liner 134 remains wrapped around the remainder of the nFET epi 126 and the pFET epi 132 that are not under the contact openings 142. The first dielectric liner 128 still remains on the nFET epi 126 in the contact opening 142.

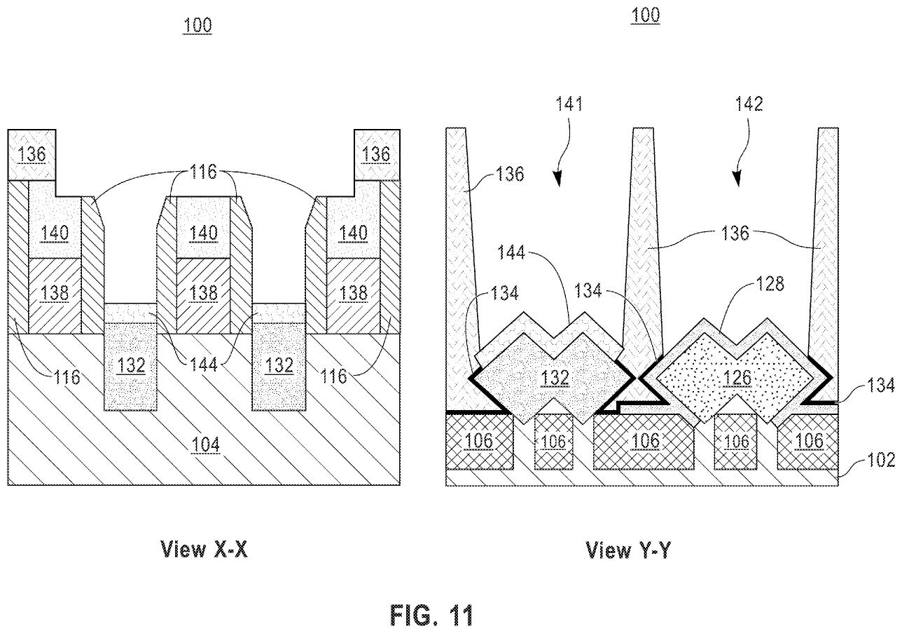

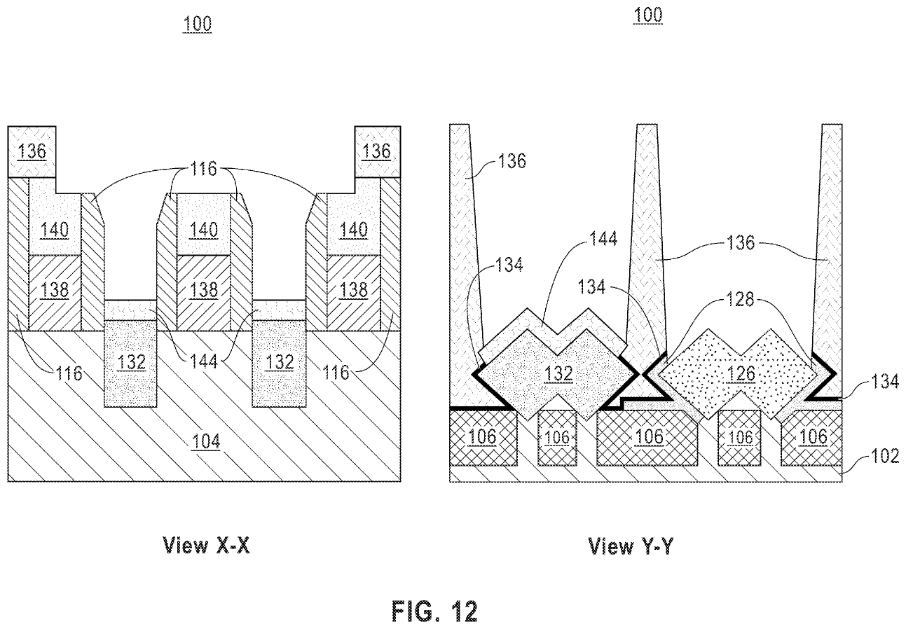

Next, in FIG. 11, the CMOS device 100 is shown after another operation. The operation is a layer of germanium (Ge) epi (or relatively high Ge % SiGe epi [e.g., with Ge %>60%]) growth 144 in the trench 141 on top of the pFET epi 132. Since the nFET epi 126 is still well covered by the first dielectric liner 128, no mask is needed to protect the nFET epi 126 during Ge epi growth 144, which saves a cost. In FIG. 12, the next operation shown is removal of the first dielectric liner 128 from the nFET epi 126 in the trench 142.

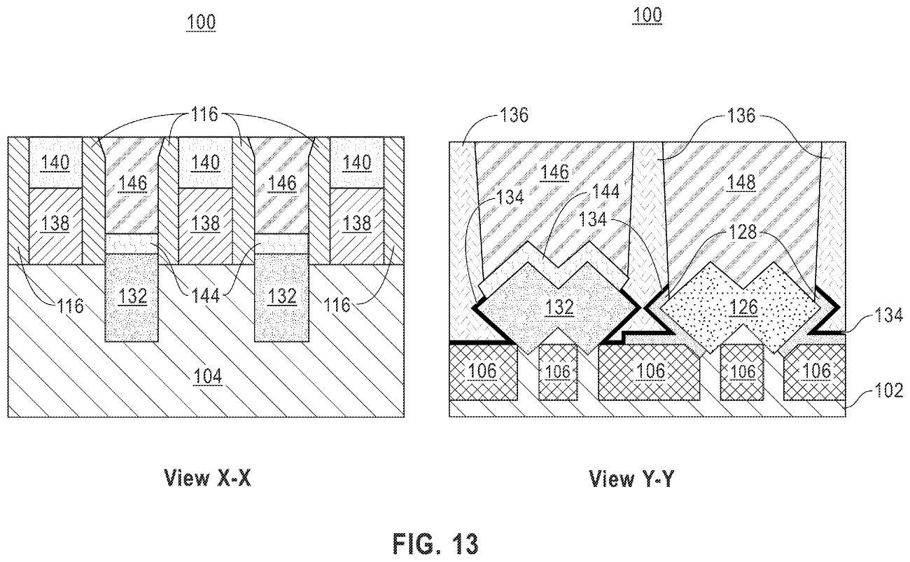

FIG. 13 depicts the CMOS device 100 after illustrative conductive contact structures 146, 148 have been formed in the trenches or contact openings 141, 142, respectively, such that they are conductively coupled to the S/D regions of the CMOS device 100. As shown, the contact structures 146, 148 (see view Y-Y) are intended to be schematic and representative in nature, as they can be formed using any of a variety of different conductive materials and by performing traditional manufacturing operations. In one illustrative embodiment, the contact structures 146, 148 can be self-aligned contact structures. The contact structures 146, 148 can also contain one or more silicide liners, such as Ti, Ni, NiPt, etc., and one or more barrier layers (such as TiN, TaN), and one or more layers of conductive metals, such as Ru, W, Co, etc. Another feature of the CMOS device 100, as shown in FIG. 13, is the dual epi liner wrapped around the nFET epi 126 (the portions not under contact trench 148), which includes the second dielectric liner 134 and the first dielectric liner 128, and single Ge epi growth 144 (Ge-containing, for example) wrapped around pFET epi 132 (the portions not under contact trench 146), which includes the second dielectric liner 134.

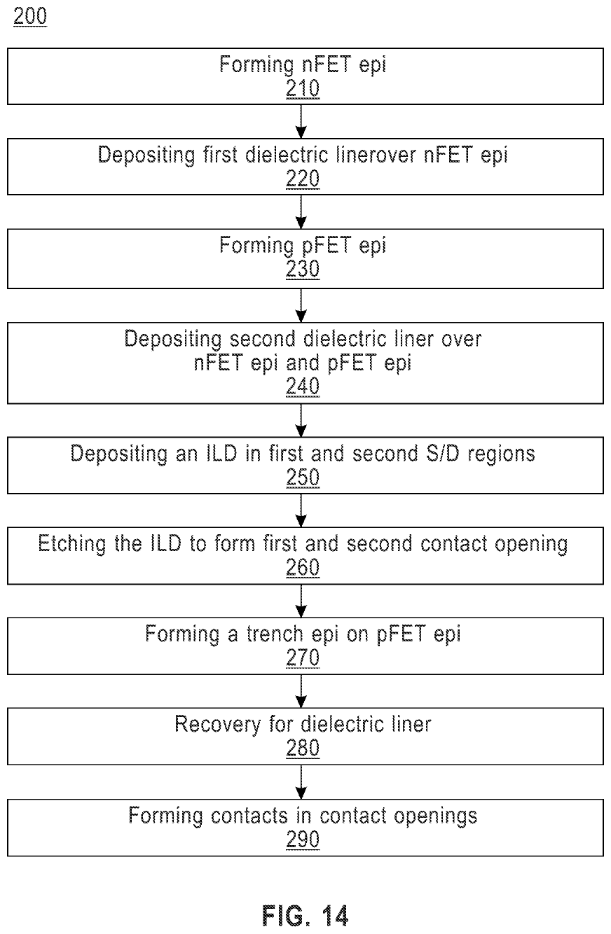

In FIG. 14, a flow diagram of operations in an example process is shown. A process of forming a complementary metal oxide semiconductor (CMOS) structure is shown as 200. One operation is shown, which is forming an nFET epi on a substrate, indicated as 210. Additionally, an operation of depositing a first dielectric liner over the nFET epi is shown at 220. Another operation is forming a pFET epi on a substrate, indicated at 230. Also, depositing a second dielectric liner over the nFET epi and the pFET epi, is shown at 240. A further operation, at 250, is depositing an ILD layer in first and second S/D regions. The operation at 260 is etching the ILD layer to form first and second contact openings. At 270, an operation of forming a trench epi (e.g., a layer of germanium (Ge) epi (or high Ge % SiGe epi with Ge %>60%) growth) on the pFET epi is included. Additionally, an operation of removing the first dielectric liner is shown at 280. Further, forming the first and second contacts in the contact openings is included at 290.

After the forming the pFET epi on the substrate operation at 210, the process 200 can further include additional operations. For example, after the forming the first contact and the second contact operation, the second dielectric liner wraps around a first portion of the pFET epi and the trench epi is located on a second portion of the pFET epi that is adjacent the first contact, and both the first and second dielectric liners wrap around a first portion of the nFET epi and a second portion of the nFET epi is adjacent the second contact.

The process 200 can include another operation of forming at least one gate stack on the substrate, wherein the gate stack includes a dummy gate structure, a gate cap layer and sidewall spacers on both sides of the dummy gate structure and the hard mask cap. Yet another possible operation can be removing the at least one gate stack and replacing each gate stack with a replacement gate stack that includes a high K metal gate and an SAC cap. A further possible operation can be etching a pattern of trenches in the substrate that is configured to provide shallow trench isolation.

For purposes of description herein, the terms “upper,” “lower,” “top,” “bottom,” “left,” “right,” “rear,” “front,” “vertical,” “horizontal,” and derivatives thereof shall relate to the devices as oriented in the figures. However, it is to be understood that the devices can assume various alternative orientations and step sequences, except where expressly specified to the contrary. Moreover, as used herein, the word “adjacent” is to be given a broad interpretation and should be interpreted to cover situations where one feature actually contacts another feature or is in close proximity to that other feature.

It is also to be understood that the specific devices and processes illustrated in the attached drawings, and described in the following disclosure, are simply exemplary embodiments of the inventive concepts defined in the appended claims. Hence, other physical characteristics relating to the embodiments disclosed herein are not to be considered as limiting, unless the claims expressly state otherwise.

For purposes of this description, certain aspects, advantages, and novel features of the embodiments of this disclosure are described herein. The disclosed processes, and systems should not be construed as being limiting in any way. Instead, the present disclosure is directed toward all novel and nonobvious features and aspects of the various disclosed embodiments, alone and in various combinations and sub-combinations with one another. The processes, and systems are not limited to any specific aspect or feature or combination thereof, nor do the disclosed embodiments require that any one or more specific advantages be present, or problems be solved.

Although the operations of some of the disclosed embodiments are described in a particular, sequential order for convenient presentation, it should be understood that this manner of description encompasses rearrangement, unless a particular ordering is required by specific language set forth below. For example, operations described sequentially can in some cases be rearranged or performed concurrently. Moreover, for the sake of simplicity, the attached figures may not show the various ways in which the disclosed processes can be used in conjunction with other processes. Additionally, the description sometimes uses terms like “provide” or “achieve” to describe the disclosed processes. These terms are high-level abstractions of the actual operations that are performed. The actual operations that correspond to these terms can vary depending on the particular implementation and are readily discernible by one of ordinary skill in the art.

As used in this application and in the claims, the singular forms “a,” “an,” and “the” include the plural forms unless the context clearly dictates otherwise. Additionally, the term “includes” means “comprises.”

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

What is claimed is:

1. A complementary metal oxide semiconductor (CMOS) device comprising:
a pFET epi that includes a single dielectric layer that wraps around a first portion of the pFET epi and a confined trench epi on a second portion of the pFET epi that is adjacent a first contact; and
an nFET epi that includes a bi-layer dielectric liner that wraps around a first portion of the nFET epi and a second portion of the nFET epi that is adjacent a second contact.

2. The device of claim 1, further comprising:
at least one gate stack wrapping around a channel region; and
a pair of source/drain regions on opposite sides of the channel region.

3. The device of claim 1, wherein the device is a planar transistor, a finFET, a nanosheet transistor, or a nanowire transistor.

4. The device of claim 1, wherein the trench epi consists of a layer of germanium (Ge) or a high Ge-percentage silicon-germanium (SiGe) with a Ge percentage greater than 60.

5. A semiconductor structure comprising:
a first field-effect transistor (FET) having a first source/drain, wherein the first source/drain comprises an nFET material;
a second FET having a second source/drain, wherein the second source/drain comprises a pFET material; and
an epi layer containing germanium (Ge) and located on the second source/drain.

6. The semiconductor structure of claim 5, further comprising:
a semiconductor substrate, wherein the first and second FETs are each located on a region of the semiconductor substrate.

7. The semiconductor structure of claim 5, wherein the epi layer consists of a layer of germanium (Ge) or a high Ge-percentage silicon-germanium (SiGe) with a Ge percentage greater than 60.

8. The semiconductor structure of claim 5, wherein the second FET includes a single dielectric liner that wraps around a first portion of pFET material and the epi layer on a second portion of the pFET material.

9. The semiconductor structure of claim 5, wherein the first FET includes a bi-layer dielectric liner that wraps around a first portion of the nFET material.

10. The semiconductor structure of claim 5, wherein the structure is a planar transistor, a finFET, a nanosheet transistor, or a nanowire transistor.

11. The semiconductor structure of claim 5, further comprising:
a first contact located on the nFET material in the first source/drain; and
a second contact located on the epi layer on the pFET in the second source/drain, wherein the epi layer consists of a layer of germanium (Ge) or a high Ge-percentage silicon-germanium (SiGe) with a Ge percentage greater than 60.

12. A method of forming a complementary metal oxide semiconductor (CMOS) structure, the method comprising:
forming an nFET epi on a substrate in a first source/drain region;
depositing a first dielectric liner over the nFET epi;
forming a pFET epi on the substrate in a second source/drain region;
depositing a second dielectric liner over both the pFET epi and the first dielectric liner that is deposited over the nFET epi;
depositing an interlayer dielectric in the first and second source/drain regions;
etching the interlayer dielectric to remove portions of the interlayer dielectric to form a first contact opening in the first source/drain region and a second contact opening in the second source-drain region, wherein during the etching, the second dielectric liner is removed within the first and second contact openings;
forming a trench epi on the pFET epi;
removing the first dielectric liner from the first contact opening; and
forming a first contact in the first contact opening and a second contact in the second contact opening.

13. The method of claim 12, wherein the substrate includes a plurality of fins configured to have the nFET epi and the pFET epi formed thereon.

14. The method of claim 12, wherein the trench epi consists of a layer of germanium (Ge) or a high Ge-percentage silicon-germanium (SiGe) with a Ge percentage greater than 60.

15. The method of claim 12, wherein the substrate includes a plurality of the fins over which at least one gate stack is formed.

16. The method of claim 12, wherein after the forming the first contact and the second contact step, the second dielectric liner wraps around a first portion of the pFET epi and the trench epi is located on a second portion of the pFET epi that is adjacent the first contact, and both the first and second dielectric liners wrap around a first portion of the nFET epi and a second portion of the nFET epi is adjacent the second contact.

17. The method of claim 16, wherein the trench epi consists of a layer of germanium (Ge) or a high Ge-percentage silicon-germanium (SiGe) with a Ge percentage greater than 60.

18. The method of claim 12, further comprising:
forming at least one gate stack on the substrate, wherein the gate stack includes a dummy gate structure, a gate cap layer and sidewall spacers on both sides of the dummy gate structure and the hard mask cap.

19. The method of claim 18, further comprising:
removing the at least one gate stack and replacing each gate stack with a replacement gate stack that includes a high K metal gate and a self-aligned contact formation (SAC) cap.

20. The method of claim 12, further comprising:
etching a pattern of trenches in the substrate that is configured to provide shallow trench isolation.
